(19) United States
(12) Patent Application Publication
(10) Pub. No.: US 2008/0316716 A1
(43) Pub. Date: Dec. 25, 2008

(54) Frame for a packaging method using flexible printed circuit boards and method thereof

(75) Inventor: Ting-An Yang, Taipei (TW)

Correspondence Address: JACKSON WALKER, L.L.P., 112 E. PECAN, SUITE 2400, SAN ANTONIO, TX, 78205, US

(73) Assignee: Tong Hsing Electric Industries Ltd.

(21) Appl. No.: 11/820,669

(22) Filed: Jun. 20, 2007

(51) Int. Cl. H05K 1/02; H05K 3/36

(52) U.S. Cl. 361/749; 29/830

(57) ABSTRACT

A frame for a packaging method using flexible printed circuit boards is provided. Before chips are bonded onto the at least one flexible printed circuit board, the frame is bonded to the at least one flexible printed circuit board to increase strength and weight of the at least one printed circuit board. Therefore, the flexible printed circuit board with the frame is used to package the chip by packaging equipment for a packaging method using printed circuit board.

### BACKGROUND OF THE INVENTION

1. Field of the Invention

The invention relates in general to a packaging method using flexible printed circuit boards, and more particularly to a packaging method having flexible printed circuit boards that can be processed by packaging equipments for a packaging method using printed circuit board.

2. Description of the Related Art

A large number of passive devices or small-sized circuit modules such as wireless communication modules have developed into an age of small outline package (SOP) and quad flat package (QFP). A thick printed circuit board (PCB) or a thin flexible printed circuit (FPC) board is often used as an IC (integrated circuit) frame. Chips are processed with the IC frame to produce electronic components products by semiconductor package.

Generally speaking, a thickness of the printed circuit board is approximately above 0.3 mm, and a thickness of the flexible printed circuit board or a thin flat is respectively below 0.2 mm or 0.12 mm. With reference to FIG. 4, in early days manufactories of producing the aforesaid small-sized electronic components use a manufacturing equipment 50 for packaging process on a chip 70 with multiple printed circuit boards 60. The manufacturing equipment 50 can be of a dispenser, a die bonder or a chip wire bonder for example. Along with a demand to downsize the electronic components to develop the manufacturing processes, if a flexible printed circuit board 61 is processed by the manufacturing equipment 50 of the printed circuit boards 60, the flexible printed circuit board 61 and the chip 70 are likely to be deviation or damaged when processed by the dispenser, the die bonder or the chip wire bonder. This is because strength of suction or pressure of the manufacturing equipment 50 of the printed circuit boards 60 is too strong for the flexible printed circuit board 61. Moreover, the flexible printed circuit board 61 is also likely to become deformed when the flexible printed circuit board is put into a soft bake device.

With reference to FIG. 4, a position deviation phenomenon is illustrated. A distance between the two flexible printed circuit boards 61 is originally D1. The two flexible printed circuit boards 61 are deviated after the processes of dispensing, bonding or wire bonding. Then the distance between the two flexible printed circuit boards 61 becomes D2, so that glue or the chip can not be accurately located at a right location. Hence a processing yield of passive device or small-sized circuit module with flexible printed circuit board 61 is reduced to less than half of the printed circuit boards 60. To downsize the electronic components is imperative; however, the conventional package process technology of the manufactories uses the packaging equipments of the printed circuit boards 60 to process the printed circuit boards 61. If this situation continues, the conventional package manufactories will not be satisfied with such low yield. Hence the package manufactories need to input more capital to buy some packaging equipments for the printed circuit boards 61, which would further reduce the manufactories' profit. Therefore how to make good use of the conventional package packaging equipments for packaging passive device or small-sized circuit module with the printed circuit board 60 to buy some time for the manufactories to purchase the packaging equipments is very important.

### SUMMARY OF THE INVENTION

An objective of the present invention is to provide a packaging method for flexible printed circuit boards and a frame for the packaging method.

In order to achieve the above objective, a chip packaging process method for the flexible printed circuit boards of the present invention has steps as follows.

At least one flexible printed circuit board and a frame are provided. A thickness of the flexible printed circuit board is under 0.2 mm. A plurality of matrix arranged circuit units is formed on the flexible printed circuit board. Each of the circuit units includes a circuit and a chip pad.

Secondly, the frame is bonded onto a periphery of the corresponding flexible printed circuit board.

Thirdly, a chip is bonded to a chip pad on the flexible printed circuit board.

Fourthly, a wire bonding is processed on a solder connection point of the chip and the flexible printed circuit board to be electrically connected.

Fifthly, a die coating is process on the flexible printed circuit board and the chip.

Sixthly, the corresponding circuit units are cut to have a plurality of electronic components.

The above processes of the frame and the flexible printed circuit board include steps as follows.

A tape is bonded on a frame. A joint of the frame and the flexible printed circuit board has the thermosetting tape. The thermosetting tape is raised near the opening of the frame. The opening of the frame is of the same size as the flexible printed circuit board.

The frame is placed to a periphery of the corresponding flexible printed circuit board. At this moment, the opening is aimed at the flexible printed circuit and is bonded downward onto the flexible printed circuit board. In this way, the tape of the frame overlays the periphery of the corresponding flexible printed circuit board.

The frame is then heated to make the tape bonded firmly with the periphery of the flexible printed circuit board.

To sum up, the present invention is to provide a frame to make the frame bonded downward onto the periphery of the flexible printed circuit board before the flexible printed circuit board is processed by dispensing, bonding or wire bonding. In this way, the flexible printed circuit board can have better strength and weight than the conventional flexible printed circuit board by bonding the frame. Hence when the flexible printed circuit board is processed by the packaging equipments of high suction or pressure, the flexible printed circuit board can avoid position deviation or damaged. Therefore, the frame provided by the present invention can assist the flexible printed circuit boards to be processed by the printed circuit boards to produce a high yield up to more than 90%.

### BRIEF DESCRIPTION OF THE DRAWINGS

FIG. 1 is a perspective view of a preferred embodiment of a frame with two separated flexible printed circuit boards in accordance with the present invention;

FIG. 2 is a perspective view of the frame and two flexible printed circuit boards in accordance with the present invention;

FIG. 3 is a flow chart of a packaging method in accordance with the present invention; and

FIG. 4 is a position deviation schematic view when a printed circuit board with chip and a flexible printed circuit board with a chip are packaged by a packaging equipment for packaging method using printed circuit boards.

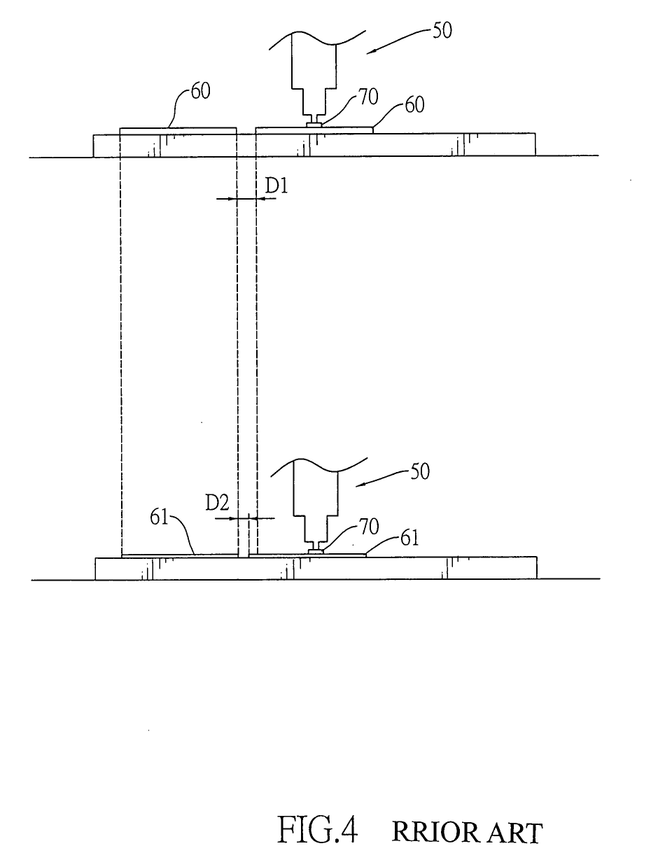

### DETAILED DESCRIPTION OF THE INVENTION

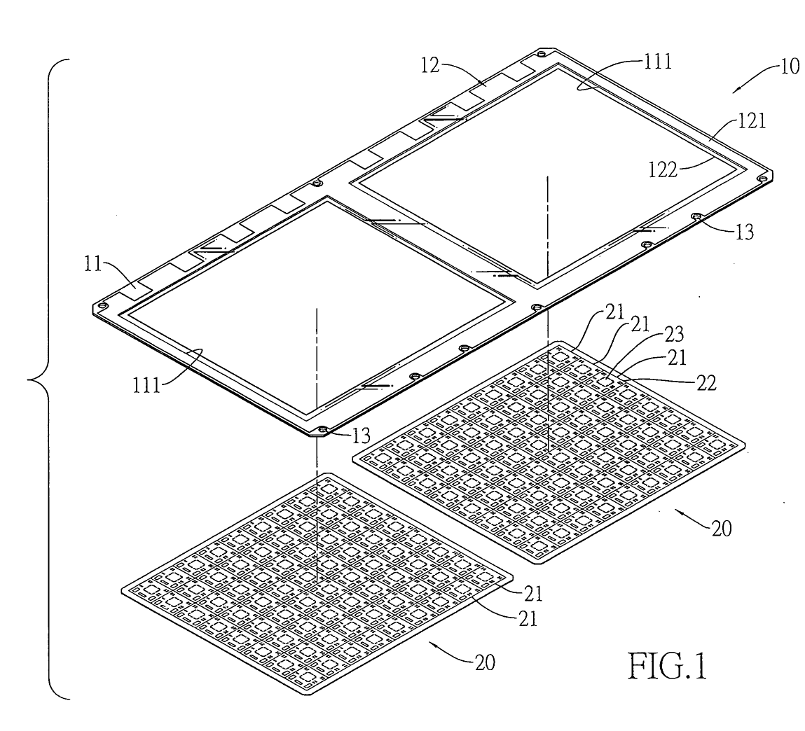

With reference to FIG. 1, a first preferred embodiment of a frame in accordance with the present invention has a body 11 and a tape 12.

At least one opening 111 is defined in the body 11. In this embodiment, there are two individual openings are defined in he body 11.

An external part 121 of the tape 12 is bonded to a periphery of the body 11, and an internal part 122 of the tape 12 is raised a periphery near each opening 111 of the body 11. Moreover, a size of each opening 111 of the body 11 fits to a size of the flexible printed circuit board 20. The flexible printed circuit boards 20 and the openings 111 are of rectangular. An internal part of the tape 12 is raised the periphery near each opening 111 of the body 11. The body 11 is made of copper or metal material. The frame 10 further has a plurality of positioning holes 13 defined on the body 11 for a packaging equipment. Moreover, the tape 12 can be of a thermosetting tape to make the flexible printed circuit boards 20 bonded to the body 11 by a heating step.

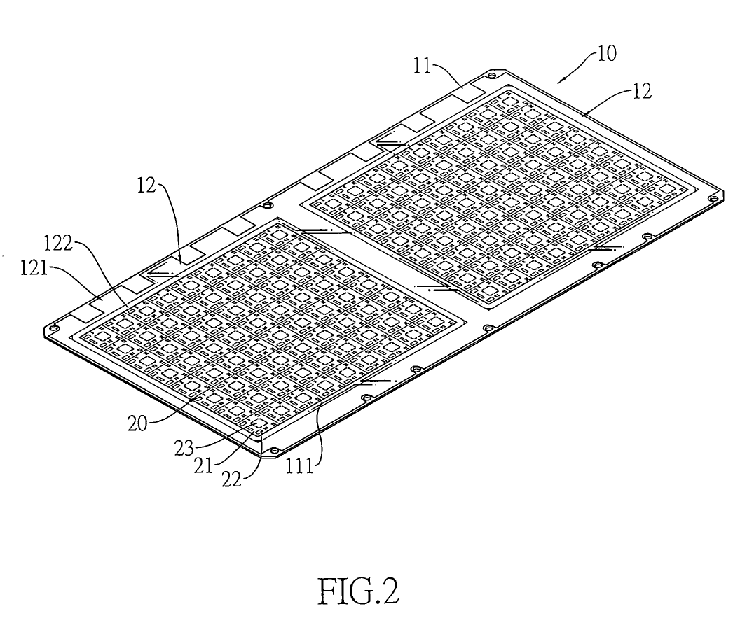

With reference to FIG. 2, the frame 10 is bonded with the two flexible printed circuit boards 20 of the corresponding size. Each flexible printed circuit boards 20 are of the same size as the opening 111 of the frame 10, and also a periphery of the flexible printed circuit board 20 overlaps the internal part of raised tape 12 of the frame 10. Thereby when the frame 10 is placed onto the two parallel flexible printed circuit boards 20, the internal part 122 of the tape 12 overlaps the periphery of the two flexible printed circuit boards 20. Since the periphery of the flexible printed circuit boards 20 usually does not form any circuit or a chip pad, the periphery of the flexible printed circuit boards 20 can be bonded to the frame 10 by the internal part of the tape 12. If the thermosetting tape 12 is used, a heating step is required to make the body 11 of the frame 10 bounded with the two flexible printed circuit boards 20.

A plurality of matrix arranged circuit units 21 is formed on the flexible printed circuit boards 20. Each of the circuit units 21 includes circuit lines 22 and a chip pad 23.

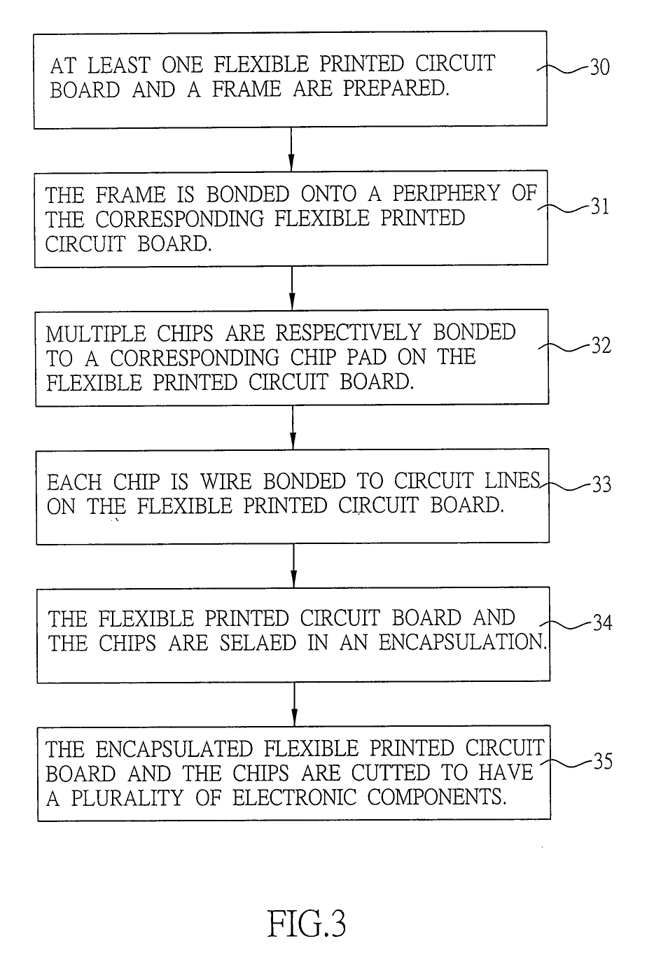

With reference to FIG. 2 and FIG. 3, a chip packaging method using the flexible printed circuit boards 20 of the present invention includes steps as follows.

In a first step (30), at least one flexible printed circuit board 20 and a frame 10 are prepared. A thickness of the flexible printed circuit board 20 is under 0.2 mm. A plurality of matrix arranged circuit units 21 is formed on the flexible printed circuit board 20. Each of the circuit units 21 includes circuit lines 22 and a chip pad 23.

In a second step (31), the frame 10 is bonded onto a periphery of the corresponding flexible printed circuit board 20.

In a third step (32), multiple chips are respectively bonded to a chip pad 23 on the corresponding flexible printed circuit board.

In a fourth step (33), each chip is wire bonded to the circuit lines of the corresponding circuit unit of the flexible printed circuit board.

In a fifth step (34), the chips and the flexible printed circuit boards are sealed in an encapsulation.

In a sixth step (35), the encapsulated flexible printed circuit boards and chips are cut to have electronic components, such as passive devices or small-sized circuit modules.

The second step (32) further has sub-steps as follows.

(a) A tape 12 is bonded on a body 11. A joint of the frame 10 and the flexible printed circuit board 20 has the thermosetting tape 12. The thermosetting tape 12 is raised near the opening 111 of the body 11. The opening 111 of the frame 10 is of the same size as the flexible printed circuit board 20.

(b) The frame 10 is placed to a periphery of the corresponding flexible printed circuit board 20. At this moment, each opening 111 is aligned to the corresponding flexible printed circuit 20 and is bonded downward onto the flexible printed circuit board 20. In this way, the tape 12 of the frame 20 overlays the periphery of the corresponding flexible printed circuit board 20.

The frame 10 is then heated to make the tape 12 bonded firmly with the periphery of the flexible printed circuit board 20.

To sum up, the present invention is to provide a frame to make the frame bonded downward onto the periphery of the flexible printed circuit board before the flexible printed circuit board is processed by dispensing, bonding or wire bonding. In this way, the flexible printed circuit board can have better strength and weight than the conventional flexible printed circuit board by bonding the frame. Hence when the flexible printed circuit board is processed by the packaging equipments of high suction or pressure, the flexible printed circuit board can avoid position deviation or damaged. Therefore, the frame provided by the present invention can assist the flexible printed circuit boards to be processed by the printed circuit boards to produce a high yield up to more than 90%.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A packaging method for flexible printed circuit boards comprising:
providing at least one flexible printed circuit board and a frame, wherein a thickness of the flexible printed circuit board is under 0.2 mm, wherein a plurality of circuit units are formed on the flexible printed circuit board, wherein each of the circuit units has circuit lines and a chip pad;
bonding the frame onto a periphery of the at least one flexible printed circuit board;
bonding multiple chips to the corresponding chip pads on the flexible printed circuit board;
electronically connecting each chip and the corresponding circuit lines on the at least one flexible printed circuit board;
incapsulating the at least one flexible printed circuit board with the chips; and
cutting the corresponding circuit units to have a plurality of electronic components.

2. The packaging method using flexible printed circuit boards as claimed in claim 1, wherein the bonding the frame onto the at least one flexible printed circuit board step uses a tape to bond a joint between the frame and the at least one flexible printed circuit board.

3. The packaging method using flexible printed circuit boards as claimed in claim 1, wherein the bonding the frame onto the at least one flexible printed circuit step board uses a thermosetting tape to bond a joint between the frame and the at least one flexible printed circuit board, so the frame, the at least one flexible printed circuit board and the thermosetting tape are further heated.

4. The packaging method using flexible printed circuit boards as claimed in claim 1, wherein the electronically connecting step uses wire bonding to connect the each chip and the corresponding circuit lines on the at least one flexible printed circuit board.

5. The packaging method using flexible printed circuit boards as claimed in claim 2, wherein the electronically connecting step uses wire bonding to connect the each chip and the corresponding circuit lines on the at least one flexible printed circuit board.

6. The packaging method using flexible printed circuit boards as claimed in claim 3, wherein the electronically connecting step uses wire bonding to connect the each chip and the corresponding circuit lines on the at least one flexible printed circuit board.

7. A frame for the packaging method using flexible printed circuit boards comprising:
a body having at least one opening wherein a size of each opening fit for that of a flexible printed circuit board; and
a tape having
an external part bonded to a periphery of the frame, and
an internal part raised at a periphery near the opening of the frame.

8. The frame for the packaging method using flexible printed circuit boards as claimed in claim 7, wherein the frame comprises two independent openings.

9. The frame for the packaging method using flexible printed circuit boards as claimed in claim 7, wherein a plurality of positioning holes are formed on the frame.

10. The frame for the packaging method using flexible printed circuit boards as claimed in claim 8, wherein a plurality of positioning holes are formed on the frame.

11. The frame for the packaging method using flexible printed circuit boards as claimed in claim 7, wherein each of the at least one opening is rectangular.

12. The frame for the packaging method using flexible printed circuit boards as claimed in claim 7, wherein the tape is a thermosetting tape.

13. The frame for the packaging method using flexible printed circuit boards as claimed in claim 8, wherein the tape is a thermosetting tape.

14. The frame for the packaging method using flexible printed circuit boards as claimed in claim 12, wherein each of the at least one opening is rectangular.

15. The frame for the packaging method using flexible printed circuit boards as claimed in claim 13, wherein each of the at least one opening is rectangular.
